(19) United States
(12) Patent Application Publication
(10) Pub. No.: US 2013/0313570 A1
(43) Pub. Date: Nov. 28, 2013

(54) MONOLITHICALLY INTEGRATED SIC MOSFET AND SCHOTTKY BARRIER DIODE

(71) Applicant: MICROSEMI CORPORATION, Bend, OR (US)

(72) Inventors: Dumitru Sdrulla, Bend, OR (US); Marc H. Vandenberg, Bend, OR (US); Bruce Odekirk, Bend, OR (US)

(73) Assignee: MICROSEMI CORPORATION, Bend, OR (US)

(21) Appl. No.: 13/902,382

(22) Filed: May 24, 2013

Related U.S. Application Data
(60) Provisional application No. 61/651,090, filed on May 24, 2012.

(51) Int. Cl. H01L 29/78; H01L 29/66

(52) U.S. Cl. CPC H01L 29/7806; H01L 29/66727
USPC 257/77; 438/237

(57) ABSTRACT

A SIC VDMOS transistor is integrated with a SiC SBD, in a seamless way, without any increase of the device area. The SiC SBD is integrated in the active area of the VDMOS by splitting the P-Wells, such that the lightly doped drift region extents all the way to the surface of semiconductor, and by trenching through the source of the VDMOS and partially through the P-Wells to reach the peak of the P-type doping in the P-Well regions. The source of the VDMOS is contacted from the top surface and from the vertical sidewalls of the trenched source and the forward voltage of the Schottky Barrier diode is tailored by using two different metals for the ohmic contact on the source and for the SBD.

### CROSS REFERENCE TO RELATED APPLICATIONS

This application claims the benefit of U.S. provisional patent application Ser. No. 61/651,090, filed May 24, 2012, herein incorporated by reference.

### BACKGROUND OF THE INVENTION

This invention relates in general terms to vertical SiC Power MOSFETs and in particular to SiC Power MOSFETs where a SiC Schottky Barrier Diode (SBD) is integrated inside of the main structure of the Power MOSFET.

Freewheeling diodes (FWD) are typical paired with switching transistors in power electronic circuitry. The FWD provides a path for current generated from the load when the switch is turned off, avoiding potential catastrophic reverse biasing of the switching transistor. FIG. 1 is an example schematic diagram of a typical implementation.

It is advantageous to integrate the switch and FWD on the same semiconductor chip to reduce cost and improve circuit reliability. In the case of a silicon MOSFET switch, the body diode (a junction diode) may be used as the FWD. In the case of a silicon IGBT implementation of a switch, a body diode does not exist as such, and an external FWD is most often used. In the case of silicon carbide MOSFET, where a body diode can be designed into the process architecture, the resulting body diode has a high forward voltage (Vf) of approximately 3 volts due to silicon carbide's wide bandgap. This high Vf leads to poor efficiencies and limitations of switching frequency; furthermore the body diode may require an excessive cross-sectional area and therefore the cost reduction advantages are not realized.

The advantages of using a Schottky Barrier diode (SBD) as a FWD are well known to those skilled in the art. Monolithically integrating an SBD with a switch has been done in silicon and explored with SiC JFETs, as described in a paper by K. Sheng, R. Radhakrishnan, Y. Zhang, and J. H. Zhao entitled “A Vertical SiC JFET with a Monolithically Integrated JBS Diode” published 2009 as part of the 21st International Symposium on Power Device and ICs, available from the Institute of Electrical and Electronics Engineers (IEEE), New York.

Unfortunately, the combination of an SBD with a vertical MOSFET is not easily accomplished, particularly while enabling design freedom for the diode current carrying capability.

For example, U.S. Pat. No. 5,164,802 (Power VDMOSFET with Schottky on the Lightly Doped Drain of the Lateral Driver) a Schottky diode is constructed on the same chip as the Power MOSFET by setting aside a certain area dedicated only to the Schottky diode (including process steps to create a lightly doped N layer where the Schottky diode is formed).

In U.S. Pat. No. 8,022,446 (Integrated Schottky Diode and Power MOSFET), as in the previously mentioned patent, a High Voltage N-well Layer (HVNW) is set aside and a Schottky barrier diode, with the proper barrier metal, is formed in that area. These two approaches have the straightforward limitation of process integration—different masks have to be designed to confine the process steps to the dedicated areas and the sequences of depositions and etches have to be carefully chosen to avoid the detrimental effect they might have on the main device (the Power MOSFET).

A better approach to the task of integrating a Schottky Barrier Diode (SBD) into the structure of a Power MOSFET is taken in U.S. Pat. No. 8,101,995 B2 (Integrated MOSFET and Schottky Device) and in U.S. publication No. 2005/0199918 A1 (Optimized Trench Power MOSFET with integrated Schottky Diode). In both these patents, the inventors interspaced the SBD's between the trench cells by eliminating the source implants at designated locations, achieving in this way a more compact design (the combined Power MOSFET-SBD area is increased only by tens of percentages in comparison to a single Power MOSFET with the same On-Resistance).

Adrian Cogan, in U.S. Pat. No. 4,811,065 (Power DMOS Transistor with High Speed Body Diode, Mar. 7, 1989), discloses how to integrate a Schottky diode inside of the P-Body of the Power DMOS transistor by widening the source opening and creating P+ regions in the middle of the area allocated to the P-well and Source Implants and diffusions. In this way, an “electric field shielding” is provided against the Schottky barrier lowering effect that might limit the blocking voltage such a structure can withstand. This has the same limitations as the previous efforts, i.e. the total area of the device has to be significantly larger to accommodate the SBD structure. Also, in his patent, Cogan makes the incorrect assumption that the front side metals for the MOSFET and the SBD are the same, and this is not generally true, especially if a high quality, high Schottky barrier diode is to be paired with a Power MOSFET aimed for high temperature applications. A low barrier Schottky will operate with low reverse leakage only at low temperatures while an SBD with high Schottky barrier metals will have very low leakage currents across a wide range of temperatures.

Therefore, there remains a need for a better structure and process for making vertical SiC Power MOSFETs with SiC Schottky Barrier Diode integrated inside the main structure of the Power MOSFET.

### SUMMARY OF THE INVENTION

Accordingly, it is a principal object of the present invention to overcome the disadvantages of prior art. In particular, certain embodiments disclosed herein enable integration of an SBD with an SiC Vertical MOSFET without adding significant additional steps and further provide flexibility to optimize the diode current-carrying capability to adjust for application requirements. Such a merged configuration realizes both cost and space savings and provides performance improvement over two discrete devices. Particular features of the integrated SBD and SiC Vertical MOSFET enabled herein comprise at least one of
Common termination of guard rings;
Optimized area diode to active MOSFET area ratio;
Reduced parasitics due to package and wiring of discrete elements; and
Increased system reliability due to reduced connections and bonding.

Additional features and advantages of the invention will become apparent from the following drawings and description.

### BRIEF DESCRIPTION OF THE DRAWINGS

FIG. 1 is a schematic diagram of a conventional 3-phase inverter having free-wheeling diodes paired with switching transistors, in which the present invention can be used.

FIG. 2 illustrates a cross section view of a SiC Power MOSFET (VDMOS) with an integrated SBD according to a first embodiment of the present invention in which the trench through the source is filled with two metals.

FIG. 3 illustrates the implementation of a second embodiment of this invention on a SiC Trench MOSFET (one low contact metal on the heavily doped source layers and a Schottky metal on the lightly doped drift region).

FIGS. 4A-C and FIGS. 5A-C are cross sections of the SiC Power MOSFET of FIG. 2 at the most important process steps.

FIG. 4A′ is a perspective view of FIG. 4A depicting a portion of a striped or inter-digitated layout.

FIGS. 6A-C are cross sections illustrating the trench process and the pull back of the interdielectric layer in further fabrication of the SiC Power MOSFET of FIG. 2 with two metal layers, one for ohmic contact on the source and one to form the Schottky barrier diode on the drift region.

FIG. 7 shows a cross section of the SiC Power MOSFET of FIG. 2 at the final metallization step to form a front side metal layer to make contact to the two metal layers in FIG. 6C.

FIG. 8 is table that contains the specific contact resistance of various metals on P and N SiC layers as presented in the literature, Sang-Kwon Lee, Ph.D., “Processing and Characterization of Silicon Carbide (6H- and 4H-SiC) Contacts for High Power and High Temperature Device Applications,” KTH, Royal Institute of Technology, Department of Microelectronics and Information Technology, Device Technology Laboratory, Stockholm, Sweden, 2002.

FIG. 9 is a model diagram and schematic that describes the main components of the parasitic NPN transistor and the internal body diode that are part of every VDMOS structure and that are being optimized and improved on by the teachings of this invention.

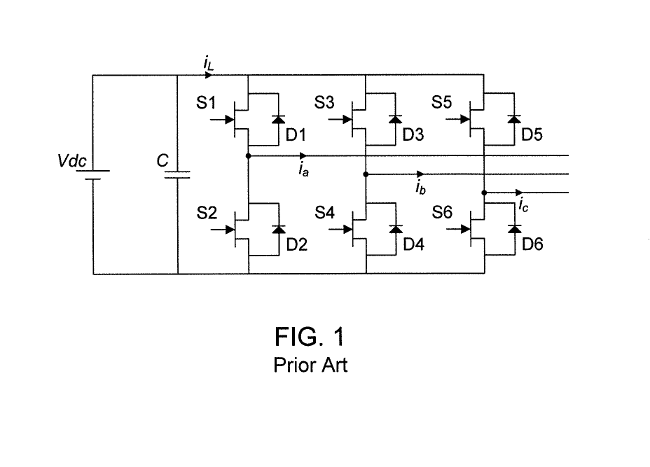

### DETAILED DESCRIPTION

Before explaining at least one embodiment of the invention in detail, it is to be understood that the invention is not limited in its application to the details of construction and the arrangement of the components set forth in the following description or illustrated in the drawings. The invention is applicable to other embodiments or of being practiced or carried out in various ways. Also, it is to be understood that the phraseology and terminology employed herein is for the purpose of description and should not be regarded as limiting. Like structural features are given like reference numerals, to avoid redundant description.

The fabrication methods employed for silicon carbide devices must take into account that dopants have very low diffusivity and that implantation activation requires high anneal temperatures.

None of the teachings in the references discussed above sensed the benefits of trenching through the source and using a pull-back process to contact the source and form the anode of the Schottky Barrier Diode. By trenching through the source, additional source area (about 20% more) is made available for the source contact and in this way the On-Resistance of the MOSFET can be lowered. In addition, by recessing the anode of the SBD, part of the holes flowing toward the front contact will not enter in the P-Body of the device and therefore the useable voltage ramp rate (dV/dt) of the integrated device will be increased.

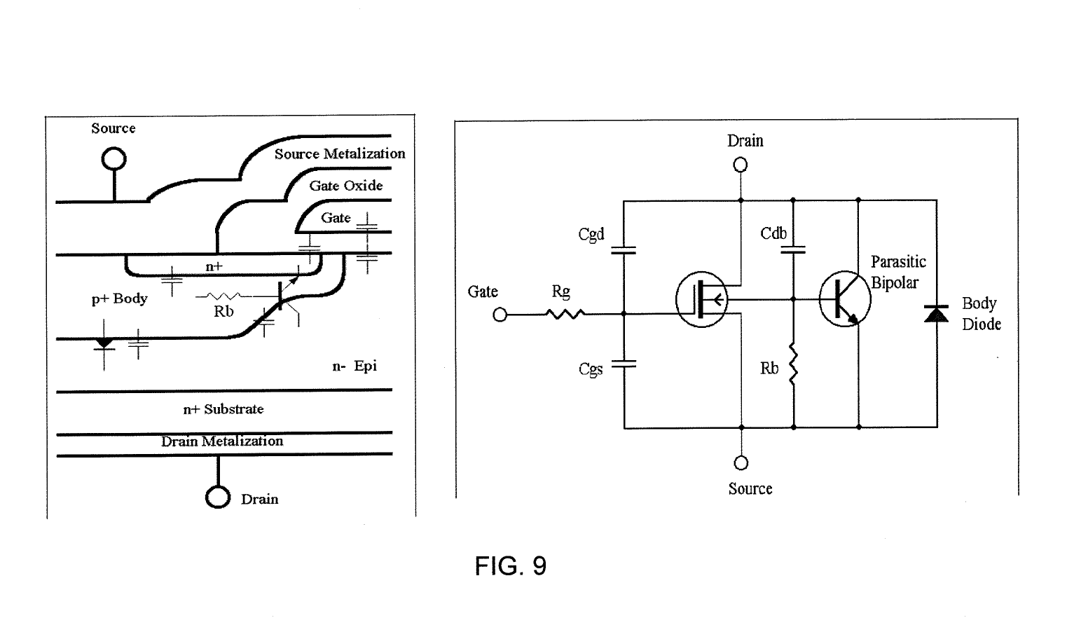

In reference to FIG. 9, in which a cross section of a VDMOS with most of the parasitic elements are illustrated, a VDMOS with the lowest Rb (the base resistance of the parasitic NPN transistor for an N-Channel MOSFET) is highly desirable as the hole current flowing underneath the source develops a voltage drop directly proportional with Rb. That voltage drop can turn on the parasitic bipolar transistor, enhancing the current and exceeding the power dissipation capability of the device. When the NPN is turned on, the Power MOSFET is destroyed. Making the length of the source as short as possible and diverting a percentage of the holes generated during the avalanche straight into the ground terminal (the source metal) rather than allowing them to flow underneath the source improves avalanche rating.

In the case of a SiC VDMOS, a shorter source also lowers the Rdson of the device as the source resistance (which is an important component of the total resistance of the part) is directly proportional to the length of the source.

The following embodiments of the present invention address the issues described above by trenching the source layer and exposing a vertical wall of the source and by inserting a Schottky Diode well below the top surface of the semiconductor. This invention can be used in conjunction with the processes described in commonly-owned U.S. Pat. No. 8,436,367, titled SiC Power Vertical DMOS with Increased Safe Operating Area, and U.S. Ser. No. 13/195,632, filed 1 Aug. 2011, titled Low Loss SiC MOSFET, incorporated by reference herein.

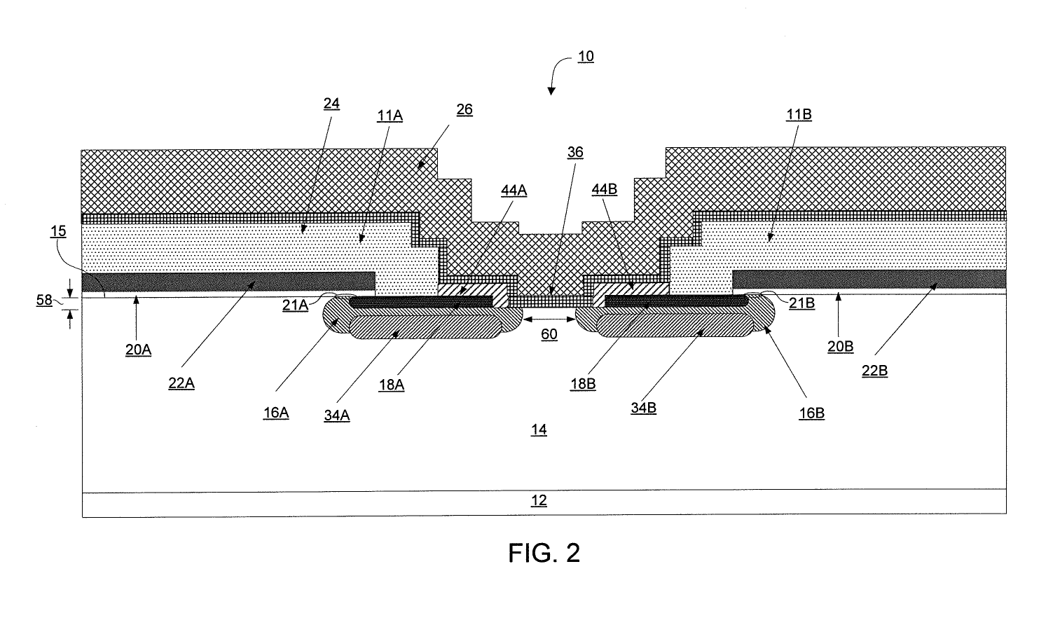

FIG. 2 provides a cross-sectional view of an integration scheme for an embodiment of device 10 which does not add masking layers. In this method, the p-well of a VDMOS transistor is split, providing an opening or gap of width 60 to the epi layer 14 between the p-wells 16A, 16B, the p-well opening being positioned equidistant between the source regions 18A, 18B of 2 adjacent transistors 11A, 11B. The Schottky barrier material 36 making contact to the epi layer 14 may, or may not, be the same material of the source contact metal 44.

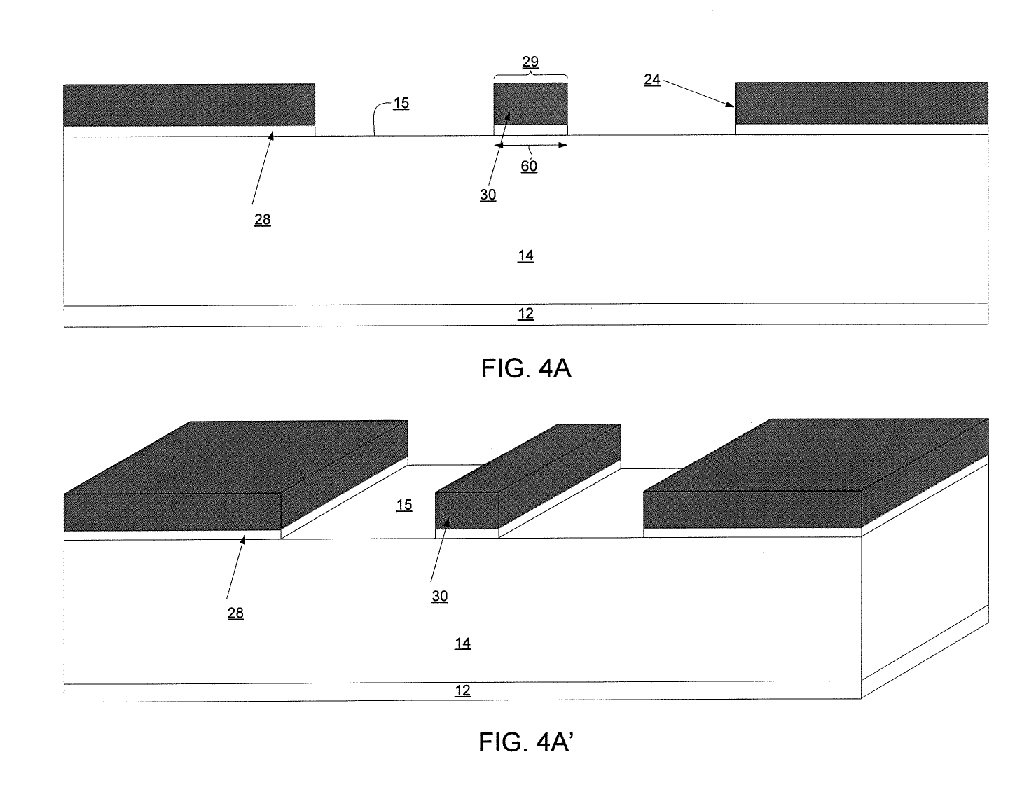

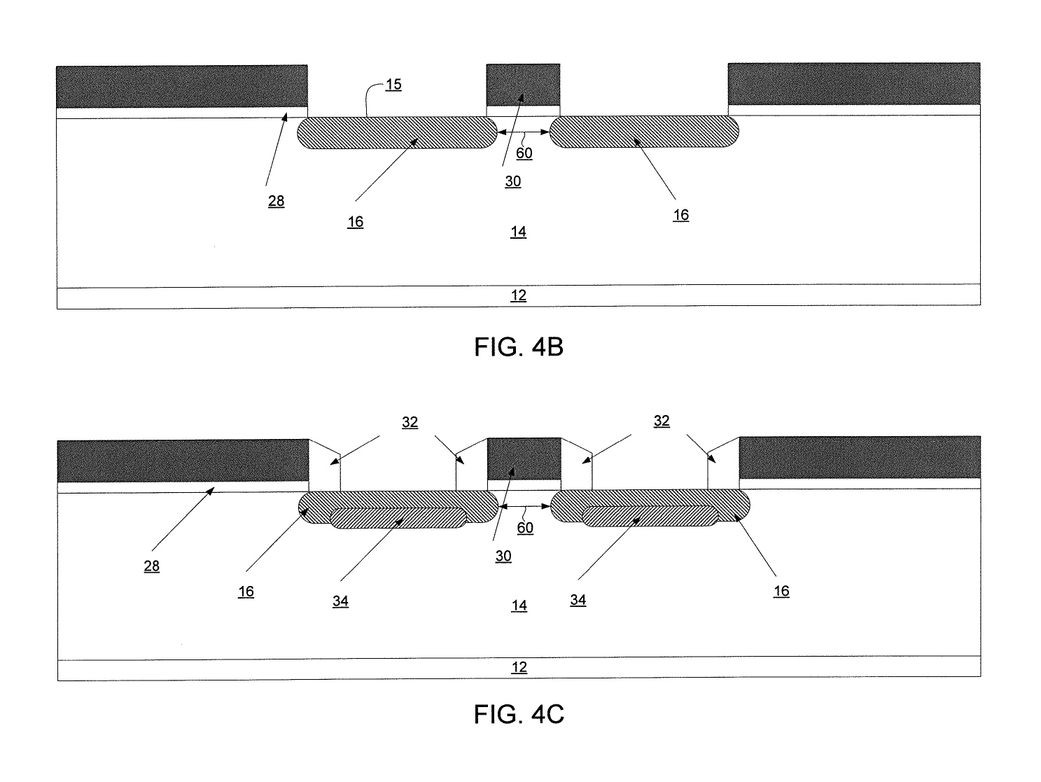

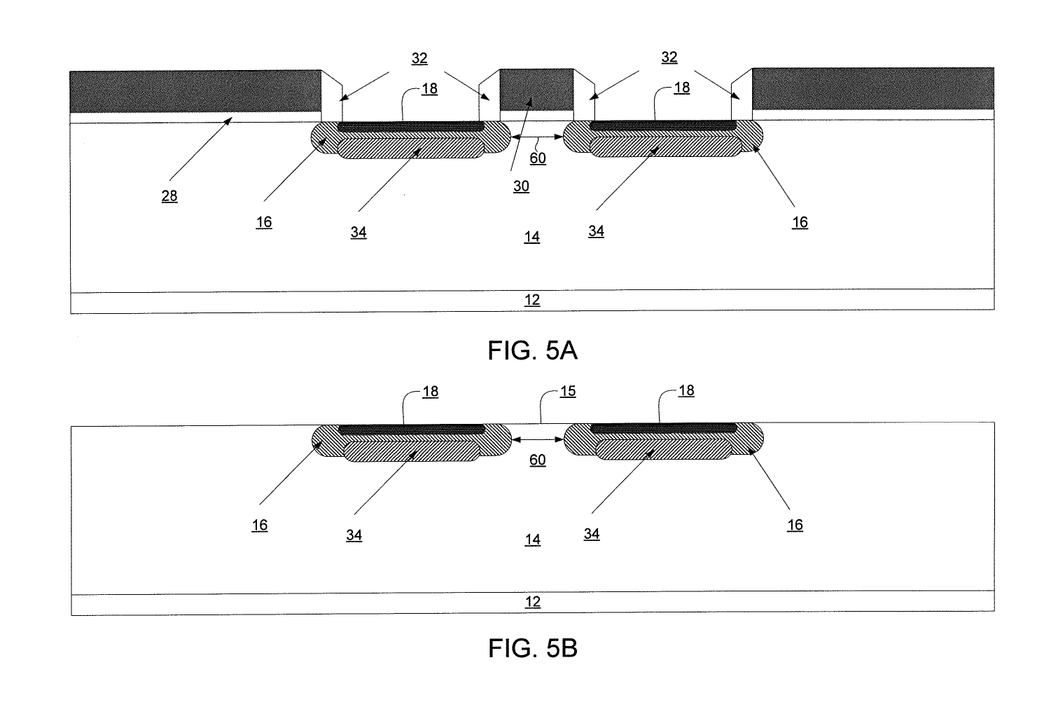

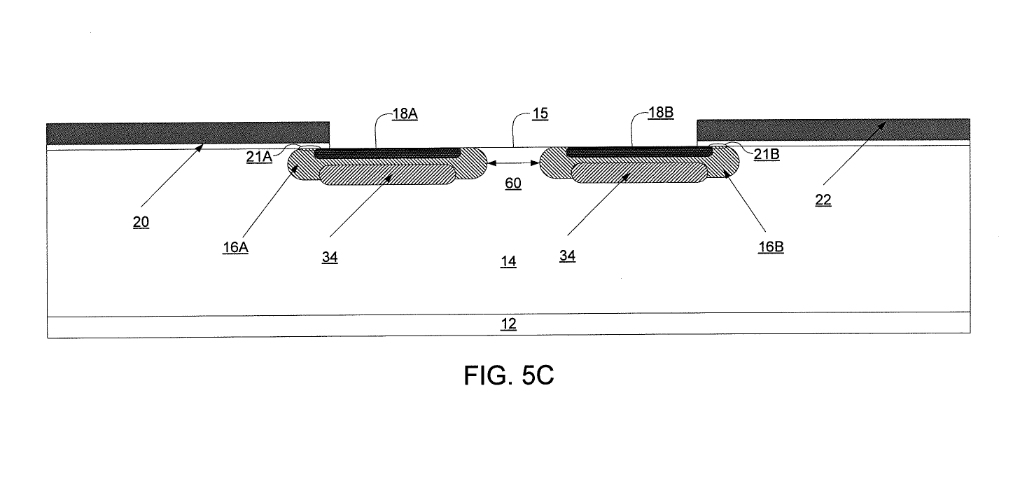

The spacing 60 between the adjacent p-wells is optimized to provide shielding of the epi layer surface from high electric fields when the diode is under reverse bias and to provide highest forward current conduction in forward bias condition. The factors contributing to the spacing optimization are the p-well implant doses, their respective profiles due to energy of implantation, and the epi doping concentration. The operative spacing 60 is set by the p-well mask itself (see FIG. 4A) and is not alignment dependent on other masking layers. If a barrier material other than the source contact metal 44 is used for the Schottky barrier material 36, a blanket mask can be used to open a window over the split p-well region for the deposition of the Schottky barrier material or conversely a blanket etch blocking mask can be used to remove material from all other regions. These masks are not critical and provide wide process tolerance.

Following are a more detailed description of the FIG. 2 embodiment and its fabrication.

FIG. 2 shows a cross sectional view of the active area of a SiC Power MOSFET (VDMOS) with integrated SBD 10. The structure begins with a heavily doped N-type SiC substrate 12 on which a lightly doped N layer 14 has been epitaxially grown. P-Wells 16 are spaced apart by a gap 60, specifically designed such that the Schottky area is large enough for the specific application. Embedded in the P-Wells, or body region 16B, are the heavily doped P-type UIS layers 34A, 34B, and the source layers 18A, 18B. The top surface 15 of layer 14 has been trenched through the source, P-Wells and the N drift layers to a base at the depth 58. The trench later on in the process is filled with low ohmic contact metal 44A, 44B and with the Schottky barrier metal 36. The rest of the cross section is easily identifiable as a VDMOSFET and it consists of the final gate oxide 20, channel regions 21A, 21B the final gate polysilicon 22, the interdielectric layer 24 (which in most cases is Boron and Phosphorus doped oxide, BPSG) and the front side electrode metal 26. Not shown is a backside drain contact metal deposited on substrate 12.

As discussed above, a VDMOS made with a very short source outperforms all other devices because its On-resistance will be lower and its unclamped inductive switching (UIS) capability will be the highest. By trenching through the source, additional side wall contact of the source 18A, 18B by contact metal 44A, 44B is made available, and that will lower the On-Resistance of the Power MOSFET.

The trench process in the P-Wells also has the advantage of providing a short path for holes generated during the avalanche process to reach the ground terminal (front side metal 26 in this case), minimizing the base resistance of the parasitic NPN transistor and therefore minimizing significantly the propensity of this transistor to be turned on under the most harsh conditions (highest current capability of the MOSFET).

By recessing the contact to the P-Wells 16A, 16B to the trench base at depth 58, the contact of the Schottky barrier metal 36 to the P-doped regions in the well is greatly improved due to the fact that for SiC Power MOSFETs a P-Well doping has a retrograde shape (higher doping deeper into SiC, lower doping toward the surface). Consequently, the Schottky barrier metal can form the required Schottky barrier on the N-drift region in gap 60 but will have a virtually ohmic contact to the body region inside of the trenched P-Wells.

The main process steps to form a Power MOSFET according to this embodiment of the invention are outlined in the following paragraphs:

Referring to FIG. 4A, on an epitaxial wafer consisting of a heavily doped N++ substrate 12 and a lightly doped N-drift layer 14, a sacrificial oxide layer 28 and a sacrificial polysilicon layer 30 are deposited and patterned using standard process steps. These steps can include the upper layer JFET doping described in U.S. Ser. No. 13/195,632, incorporated by reference herein. What is unique in the case of this invention is that two P-Wells are going to be defined with the proper mask 24 such that a split well structure with the gap 60 between the P-wells is formed.

This concept of blocking the P-Well implant using a patterned sacrificial oxide 28 and sacrificial poly 30, in between what will ultimately become the gate oxide and the polysilicon gates of the final VDMOS, is applicable to any type of layout topography as shown in FIG. 4A′. Examples include a repeating stripe configuration or an interdigitated structure (comb-like gate fingers interspaced by openings where the P-Wells are formed) or a cellular design of any shape (squares, hexagons or rectangles or any other design of the polysilicon gate layout). For each one of these layouts the designer just has to add, inside of the P-Well opening, the stack of oxide 28 and poly 30 with a properly designed width 29 such that the P-Well implants on the left and right side of the oxide-polysilicon stack will not merge together and leave sufficient N-drift region to form a Schottky Diode of the required current rating.”

Referring to FIG. 4B, following the patterning of the sacrificial poly layer 30 and sacrificial oxide layer 28, a high temperature (in the range of 500-1000 C) implantation of a P-type layer (such as Aluminum or Boron) takes place and the P-wells 16 are formed at the desired depth and with the designed doping profile. In most cases, the P-well implant is done at high energies and it is not unusual to perform three different implants, at three different energies and doses, such that the final implant (the one closest to the upper surface 15) sets the required surface doping for the threshold voltage of the MOSFET.

At FIG. 4C, a thick oxide is deposited and dry etched on the wafers, such that an oxide spacer 32 is created on the side wall of the sacrificial poly layer 30. The function of these oxide spacers 32 is to offset the next implants. The first implant is a deep P-type implant 34 (usually called the UIS implant because its presence enhances the unclamped inductive switching (UIS) capability of the Power MOSFET). Second is the source implant 18 (FIG. 5A) done at significantly lower energy (in most cases the species used for the source implant is Nitrogen, but other species suitable to form N++ layers in SiC can be used at this step).

At the next step in the process flow shown in FIG. 5B, after the source implant, the sacrificial poly layer 30 and the sacrificial oxide layer 28 are stripped using conventional methods well known in the industry. Following that, a carbon layer may be deposited (not shown in the cross sections) and the species implanted in SiC are activated employing a high temperature anneal process (usually done around 1650 C in an inert atmosphere). Post high-temperature anneal, the carbon cap is removed. FIG. 5B is a representation of the SiC wafers with all implanted layers activated.

Turning to FIG. 5C, final gate oxide layer 20 and final poly layer 22 (which may be doped with Phosphorus or converted to a polycide) are formed and then patterned to provide gate structures over the channel regions 21A, 21B at opposite ends of the respective source and body regions 16A/18A, 16B/18B.

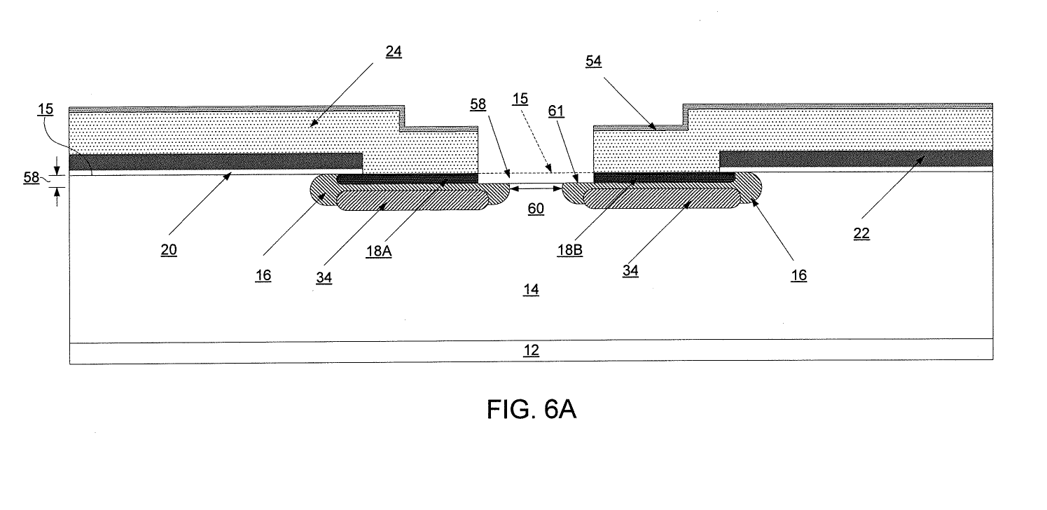

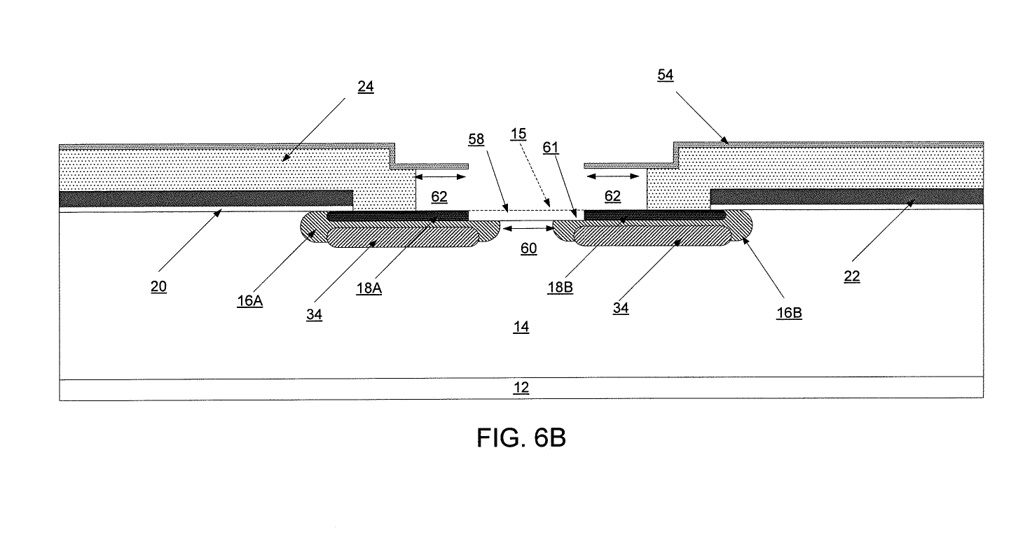

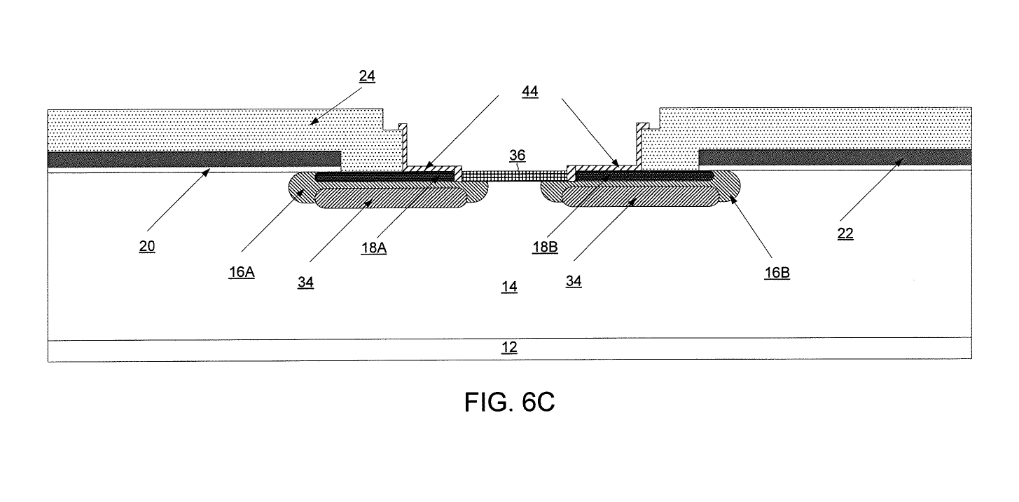

Next, in FIG. 6A, an interlayer dielectric layer 24 (BPSG) and a nitride layer 54 are deposited, patterned and etched using a dry etch process to expose surface 15 and opposed end portions of the body and source regions 16, 18 symmetrically about gap 60. After clearing the BPSG layer 24, a trench 56 is formed in the SiC material from the top surface 15 to the depth 58 in the epi layer semiconductor material. The trench depth 58 is tailored such that it removes entirely the source layer (heavily doped N++) and stops close to or at the peak doping of the P-wells 16. By designing the trench depth in this way, the conditions for low On-resistance of the MOSFET are created. The trench forms a notch 61 at each end that truncates the opposed lateral ends of the source regions 18A, 18B symmetrically about the gap 60.

In FIG. 6B, with the Nitride layer 54 still in place, a lateral wet etch of the BPSG layer is performed at the distance 62, tailored such that enough of each source 18A, 18B is exposed for the subsequent formation of the ohmic contact while the remaining thickness of the interdielectric layer 24 is still sufficient to meet the requirements of the gate-source maximum rating voltage. This novel pull-back process using a nitride layer replaces a conventional resist process, which has the risk of lifting during the lateral etch and creating shorts between the gate and the source. When the desired lateral depth is reached, the nitride layer can be stripped using conventional processes like hot phosphoric acid.

Referring to FIG. 6C, with the nitride layer 54 removed, ohmic contacts 44 on the source and the delineation of the Schottky barrier metal 36 are formed. The ohmic contact layer 44 covers not only the upper surface of source regions 18A, 18B but also provides a vertical contact portion that converts the truncated ends of the source regions and contacts the body regions in the location of notches 61 (see FIG. 6B).

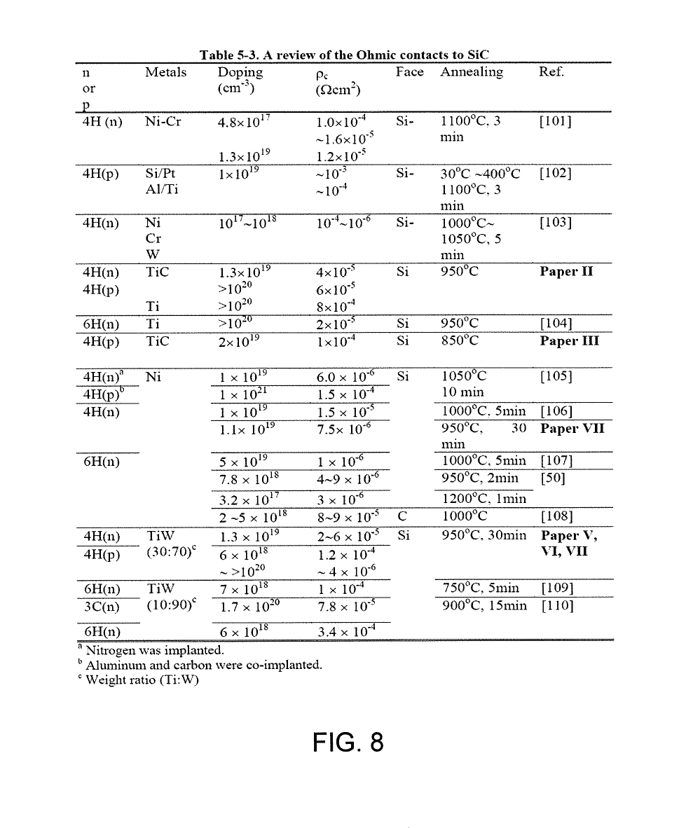

For best performance of the MOSFET, it is important to form ohmic contacts to the source with the lowest possible contact resistance. For SiC devices, a specific contact resistivity of ˜1×10⁻⁶ ohm-cm² represents the current state of the art. As shown in the Table in FIG. 8, this resistivity is most readily obtained by use of nickel silicide as the ohmic contact metal, formed by reacting nickel with the SiC. This is most typically done in two steps, with an initial moderate temperature anneal performed in the range 400-600 C to form a mixed phase silicide followed by a high temperature anneal (800-1000 C) to establish a uniform silicide phase with the lowest contact resistance.

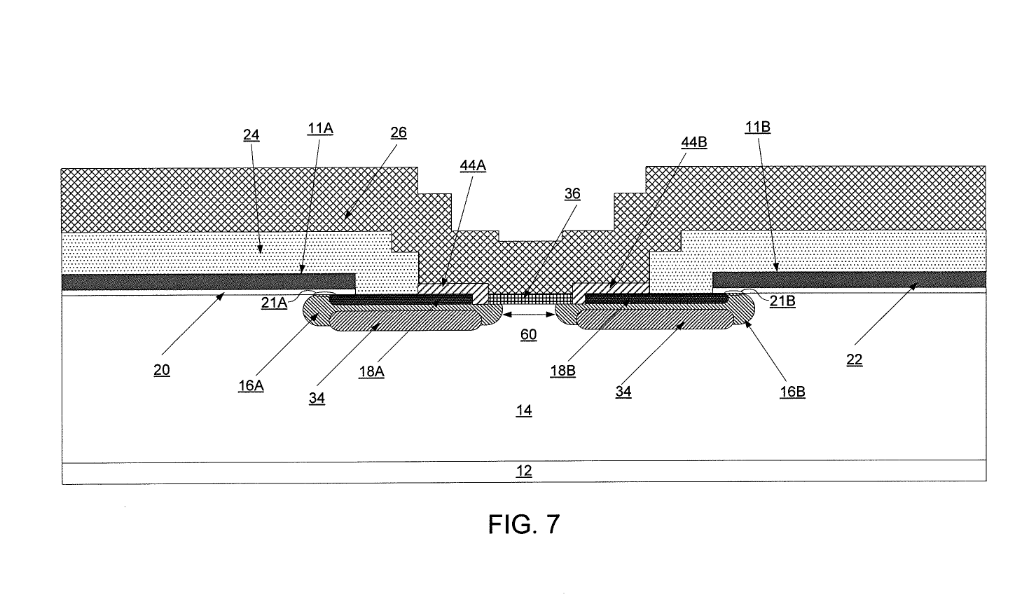

The preferred sequence of process steps is to form the ohmic contact 44 on the source first, as it requires the above-mentioned high anneal temperatures, and then forming the Schottky barrier diode, possibly together with the sputtering/evaporation of the front side metal 26 (FIG. 7). These two metals (Schottky barrier 36 and front metal 26) can be patterned and etched in the same photomasking step.

The final device will be completed with a backside metal and front side passivation layers, not shown here for reasons of simplicity.

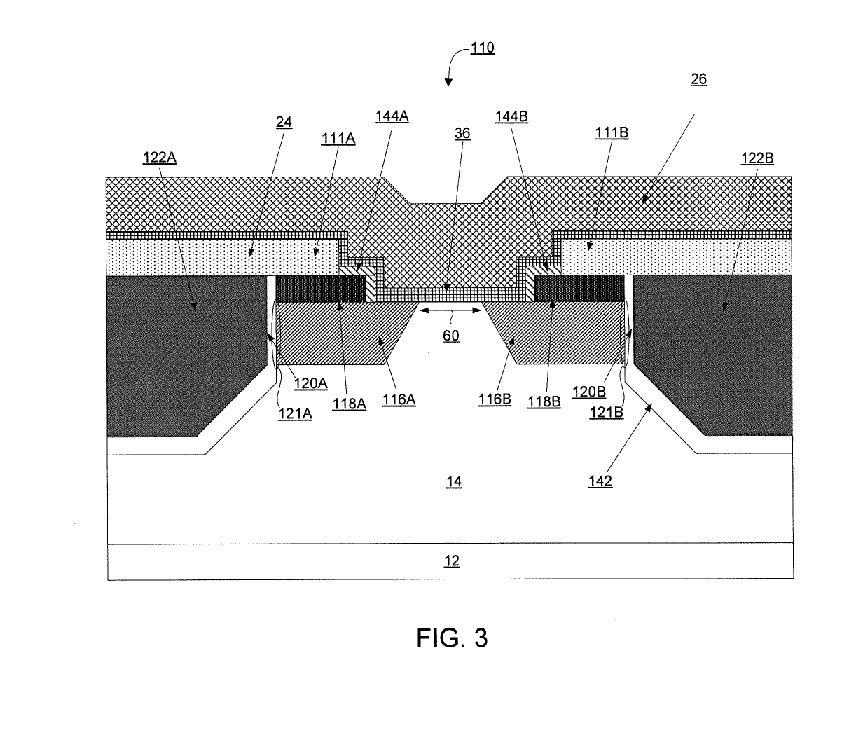

This invention is not limited to planar VDMOS but can very well be applied to a Trench MOSFET 110 with a vertically oriented-gate and channel as illustrated in FIG. 3. Similar structural features are given the same reference numbers as in FIG. 2, plus 100. Apart from the vertical orientation of the gate oxide and channel from FIG. 2 to FIG. 3, the foregoing description of the FIG. 2 embodiment and its fabrication process applies to fabrication of the FIG. 3 embodiment.

It is appreciated that certain features of the invention, which are, for clarity, described in the context of separate embodiments, may also be provided in combination in a single embodiment. Conversely, various features of the invention which are, for brevity, described in the context of a single embodiment, may also be provided separately or in any suitable subcombination. In particular, the invention has been described with an identification of each powered device by a class, however this is not meant to be limiting in any way. In an alternative embodiment, all powered device are treated equally, and thus the identification of class with its associated power requirements is not required.

Unless otherwise defined, all technical and scientific terms used herein have the same meanings as are commonly understood by one of ordinary skill in the art to which this invention belongs. Although methods similar or equivalent to those described herein can be used in the practice or testing of the present invention, suitable methods are described herein.

All publications, patent applications, patents, and other references mentioned herein are incorporated by reference in their entirety. In case of conflict, the patent specification, including definitions, will prevail. In addition, the materials, methods, and examples are illustrative only and not intended to be limiting.

It will be appreciated by persons skilled in the art that the present invention is not limited to what has been particularly shown and described hereinabove. Rather the scope of the present invention is defined by the appended claims and includes both combinations and subcombinations of the various features described hereinabove as well as variations and modifications thereof which would occur to persons skilled in the art upon reading the foregoing description.

1. An integrated silicon carbide (SiC) vertical power MOSFET and Schottky barrier diode structure, comprising:
a SiC substrate including an upper layer of a first dopant type defining a drift region extending from an upper surface of the substrate depthwise into the substrate;
first and second body regions in the upper layer and adjoining the upper surface of the substrate and spaced apart about the drift region, the body regions being of a second dopant type opposite the first dopant type and having opposed lateral peripheries forming a pair of spaced-apart first PN junctions with the drift region and opposite peripheries forming second PN junctions with a drain region;
first and second source regions positioned respectively in the first and second body regions across the upper surface of the substrate to define first and second source contact regions and having opposite ends located adjacent the opposite peripheries of the body region and spaced from the second PN junctions to define first and second channel regions between the respective source regions and second PN junctions;
a gate oxide layer extending along each of the channel regions;
a gate conductor contacting the gate oxide; and
first and second source conductor ohmic contact regions contacting an upper surface of the source regions and portions of the body regions spaced apart from each other across the drift region; and
a Schottky barrier metal layer contacting the upper layer of a first dopant type defining the drift region portion to form a Schottky barrier diode with the drift region between the spaced-apart first PN junctions;
the substrate including a trench in the upper layer of the substrate spanning the drift region and the first PN junctions, and extending depthwise through portions of the first and second source regions into the opposed lateral peripheries of the first and second body regions, the trench containing the Schottky barrier diode.

2. An integrated silicon carbide (SiC) vertical power MOSFET and Schottky barrier diode structure according to claim 1, wherein the first and second body regions have a spacing contained within the trench which defines an area of the Schottky barrier diode.

3. An integrated silicon carbide (SiC) vertical power MOSFET and Schottky barrier diode structure according to claim 1, wherein the first and second source conductor ohmic contact regions contact an upright surface of the source regions along opposite sidewalls of the trench and contact adjacent portions of the body regions at a base of the trench.

4. An integrated silicon carbide (SiC) vertical power MOSFET and Schottky barrier diode structure according to claim 1, wherein the body and source regions, the channel regions and the gate oxide layer are substantially planar with the upper surface of the substrate.

5. An integrated silicon carbide (SiC) vertical power MOSFET and Schottky barrier diode structure according to claim 1, wherein the body and source regions are substantially planar with the upper surface of the substrate and the channel regions and the gate oxide layer extend depthwise along sidewalls of a trench containing the gate conductor.

6. An integrated silicon carbide (SiC) vertical power MOSFET and Schottky barrier diode structure according to claim 1, wherein the body regions have a depthwise retrograde doping concentration and trench has a base at a depth in the body regions in which the body region doping concentration is greater than the body region doping concentration at the upper surface of the substrate, the base of the trench being contacted by the Schottky barrier metal layer.

7. A method of making an integrated silicon carbide (SiC) vertical power MOSFET and Schottky barrier diode structure, the method comprising:
providing a SiC substrate including an upper layer of a first dopant type defining a drift region extending from an upper surface of the substrate depthwise into the substrate;
forming first and second body regions in the upper layer and adjoining the upper surface of the substrate and spaced apart about the drift region, the body regions being of a second dopant type opposite the first dopant type and having opposed lateral peripheries forming a pair of spaced-apart first PN junctions with the drift region and opposite peripheries forming second PN junctions with a drain region;
forming first and second source regions positioned respectively in the first and second body regions across the upper surface of the substrate to define first and second source contact regions and having opposite ends located adjacent the opposite peripheries of the body region and spaced from the second PN junctions to define first and second channel regions between the respective source regions and second PN junctions;
forming a gate oxide layer extending along each of the channel regions and a gate conductor layer contacting the gate oxide layer;
forming a trench in the upper layer of the substrate spanning the drift region and the first PN junctions, and extending depthwise through portions of the first and second source regions into the opposed lateral peripheries of the first and second body regions;
forming first and second source conductor ohmic contact regions contacting an upper surface of the source regions and the opposed lateral peripheries of the body regions; and
forming a Schottky barrier metal layer contacting the upper layer of a first dopant type within the trench to form a Schottky barrier diode.

8. A method of making an integrated silicon carbide (SiC) vertical power MOSFET and Schottky barrier diode structure according to claim 7, in which a first patterning step is used to define a width of the drift region between the first and second body regions, said width corresponding to a dimension of the Schottky barrier diode.

9. A method of making an integrated silicon carbide (SiC) vertical power MOSFET and Schottky barrier diode structure according to claim 8 in which the first patterning step includes forming an implant mask for implanting the body regions.

10. A method of making an integrated silicon carbide (SiC) vertical power MOSFET and Schottky barrier diode structure according to claim 9 in which sidewall spacers are added to the implant mask for implanting the source regions.

11. A method of making an integrated silicon carbide (SiC) vertical power MOSFET and Schottky barrier diode structure according to claim 8, in which a second patterning step is used to define a width of the trench spanning the drift region and the first PN junctions.

12. A method of making an integrated silicon carbide (SiC) vertical power MOSFET and Schottky barrier diode structure according to claim 8, in which the second patterning step includes forming an etching mask for etching the trench.

13. A method of making an integrated silicon carbide (SiC) vertical power MOSFET and Schottky barrier diode structure according to claim 12, in which, after forming the trench, the etching mask is pulled back a predetermined distance from opposite sides of the trench to expose the upper surface over a portion of each of the source regions.

14. A method of making an integrated silicon carbide (SiC) vertical power MOSFET and Schottky barrier diode structure according to claim 7, in which the body regions are implanted with a retrograde doping profile and the trench is etched depthwise into the lateral peripheries of the body regions to a depth in which the doping concentration of the body regions is greater than a doping concentration thereof at the upper surface.

15. A method of making an integrated silicon carbide (SiC) vertical power MOSFET and Schottky barrier diode structure according to claim 7, in which the trench is formed so as to expose vertical sidewall portions of the source regions and the ohmic contact regions further contact the source regions along the exposed vertical sidewall portions.

16. A method of making an integrated silicon carbide (SiC) vertical power MOSFET and Schottky barrier diode structure according to claim 15, in which the Schottky barrier metal layer is formed to further contact the opposed lateral peripheries of the body regions within the trench on opposite sides of the drift region.
